(19) United States
(12) Patent Application Publication
(10) Pub. No.: US 2020/0274037 A1
(43) Pub. Date: Aug. 27, 2020

(54) CORE-SHELL NANOPHOSPHOR AND LIGHT SOURCES

(71) Applicant: NanoSi Advanced Technologies, Inc., Champaign, IL (US)

(72) Inventors: Munir H. NAYFEH, Urbana, IL (US); Aman TAUKENOV, Nur-Sultan (Astana) (KZ)

(21) Appl. No.: 16/529,442

(22) Filed: Aug. 1, 2019

Related U.S. Application Data
(60) Provisional application No. 62/810,082, filed on Feb. 25, 2019.

(51) Int. Cl. H01L 33/50; H01L 25/075; C09K 11/59; C09K 11/54; C09K 11/56; C09K 11/77

(52) U.S. Cl. CPC H01L 33/504; H01L 25/0753; C09K 11/592; H01L 2933/0041; C09K 11/562; C09K 11/7728; H01L 2933/0033; C09K 11/54

(57) ABSTRACT

Nanophosphors are provided comprising a nanoparticle core having an attached shell of smaller silicon nanoparticles attached via hydrogen bonding. Example methods for forming a nanophosphor comprise providing a silicon nanoparticle (SiNp) colloid including Si nanoparticles, and transferring the colloid to a solid state comprising silica and/or phosphor particles. Drying is allowed such that the Si nanoparticles form a coating on the particles with hydrogen bonds.

### PRIORITY CLAIM AND REFERENCE TO RELATED APPLICATION

This application claims priority to U.S. Provisional Application Ser. No. 62/810,082, filed Feb. 25, 2019, which application is incorporated in its entirety by reference herein.

### FIELD

A field of the invention is phosphors. An example application is to solid state lighting. A specific example is solid state white lighting.

### BACKGROUND

Solid state lighting remains an elusive goal, because broad spectrum quality white light is not provided. Research into solid state lighting has been conducted since the introduction of the first commercial light emitting diodes (LED) in the 1960s. Initial systems lacked a blue component, and blue emitting LEDs were developed much later. Since the introduction of the blue LED, there have been many proposed systems to produce white light from LED sources.

Example systems include blue LED-pumped systems. These systems do not use a blue phosphor component. The blue component of the white light is thus provided directly from the pumping LED. A recent advancement in such systems is provided by Scianna et al, U.S. Pat. No. 8,143,079. That patent describes use of a white light emission device that has a cascade configuration of luminescent silicon nanoparticle films to convert the output of a UV/blue light LED into white light output. Red, green, and blue films are stacked on the UV/blue light LED. These films allow the blue light of the LED to pass through, but absorb the UV light. The absorbed UV light produces respective red, green and blue fluorescence from the cascaded nanoparticle films. The device produces wide spectrum white light.

However, reliance on the blue LED pumping source presents a significant hurdle to achieving a high correlated color temperature (CCT) and color rendering index (CRI) at the same time. These are measures that help compare the quality of a white light source to natural light.

Others have proposed using high-power UV LEDs to drive white light generation. UV radiation is potentially harmful, and its transmission must be limited. High power UV LEDs have to be used in a configuration that captures and converts the UV radiation. This conversion requires an efficient wide band red converter. Few good efficient red phosphors, whether sulfide-, nitride-, or oxide based have been known. Typical spectra from known converters are dominated by sharp line spectra with branching ratios that depend on the UV wavelength, which is not ideal for color mixing. The red phosphor yttrium oxide-sulfide activated with europium, for example, has been investigated in UV-based lighting. Co-doped phosphate materials have been synthesized for near UV pumping, which provided a peak wavelength of 610 nm. See, Cho et al, “Study of UV excited white light-emitting diodes for optimization of luminous efficiency and color rendering index,” Phys. Status Solidi (RRL) 3, 34 (2009).

Another approach for wavelength conversion on a UV-LED based source has been the use of (CdSe)ZnSe quantum dots to produce a hybrid red emitting LED. See, Song et al., “Red light emitting solid state hybrid quantum dot-near-UV GaN LED devices,” Nanotechnology 18 255202 (2007). The (CdSe)ZnSe quantum dots were used as red phosphors and a GaN UV-LED provided excitation. This device did not provide white light emission, however, instead only providing red emissions. Conventional red phosphor converters provide spectra dominated by sharp lines and suffer from availability and stability issues which are not ideal for color mixing in display or solid state lighting applications.

An advance was provided by Nayfeh U.S. Pat. No. 9,862,885. That patent provides, for example, a nanophosphor containing red silicon nanoparticles dispersed in a medium with a blue phosphor and a green phosphor. The medium can be room temperature vulcanized silicone. In example disclosed embodiments, the silicon nanoparticles, ZnS:Ag and ZnS:Cu,Au,Al are mixed in ratios that simultaneously provide a predetermined correlated color temperature (CCT) and color rendering index (CRI). The emission spectra of the nanophosphor can be tuned to a D65 standard of solar radiation.

### SUMMARY

Embodiments of the invention provide, among other things, a nanophosphor comprising a nanoparticle core having an attached shell of smaller silicon nanoparticles attached via hydrogen bonding.

In example embodiments, the nanoparticle core comprises one or more of silica, zinc oxide (ZnO), zinc sulfide (ZnS), or yttrium oxide-sulfide activated with europium (Y₂O₂S:Eu). In example embodiments, in combination with any other features, the nanoparticle core is doped with metal ions.

Other embodiments of the invention include light emitting devices (light sources) including nanophosphors as disclosed herein. In example embodiments, any of the nanophosphors disclosed herein may be bonded to a solid state light source. Methods for making such light emitting devices are also provided.

Other embodiments of the invention provide a method for forming a nanophosphor. A silicon nanoparticle (SiNp) colloid including Si nanoparticles is provided, and the colloid is transferred to a solid state comprising particles of one or more of silica and/or phosphor particles. Such particles can include, for instance, one or more of silica, ZnO, ZnS, or yttrium oxide-sulfide activated with europium (Y₂O₂S:Eu). Drying is allowed such that the Si nanoparticles form a coating on the particles with hydrogen bonds.

Other embodiments of the invention provide a method for forming a nanophosphor such as one or more of the nanophosphors disclosed herein comprising applying core powder to a plate, drying a colloid of silicon nanoparticles in isopropyl alcohol onto the plate with the core powder, and allowing drying such that the Si nanoparticles form a coating on the core powder with hydrogen bonds.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 shows an example core-shell nanophosphor including silicon nanoparticles (SiNp) according to an embodiment of the invention.

FIG. 2 shows an example luminescent spectrum for a coated glass powder according to an embodiment of the invention.

FIG. 3 shows photos of example luminescent core-shell (Si nanoparticle-silica) powder taken with 365 nm irradiation.

FIG. 4 shows an example Zn-based core shell nanophosphor according to an embodiment of the invention.

FIG. 5 shows a core-shell powder including zinc sulfide (ZnS) doped with copper, aluminum, and gold (ZnS:Cu,Au,Al) according to an embodiment of the invention.

FIGS. 6A-6B show a crystalline structure of a core-shell formed with the red phosphor yttrium oxide-sulfide activated with europium, and a hybrid core-shell, respectively, according to an embodiment of the invention.

FIG. 7 shows luminescent photos for examples of SiNp in Tetrahydrofuran (THF) (left) and in isopropyl alcohol (right).

FIG. 8 (top, left to right) shows gives from green, red, blue and white silica SiNp core-shells according to an embodiment of the invention. FIG. 8 (bottom, left to right) shows four different white mixtures with different shades of resulting white.

FIG. 9 shows effects of water on example nano silicon.

FIG. 10 shows viability of SiNp in hydrochloric acid (HCl) (left) and in alkali (KOH) (right).

FIG. 11 shows an example fabrication method for a light emitting diode (LED) including SiNp according to an embodiment of the invention.

FIGS. 12A-12B show example LED devices in which a red LED is omitted (FIG. 12A) and in which both a red LED and red phosphor are omitted (FIG. 12B).

### DETAILED DESCRIPTION OF THE PREFERRED EMBODIMENTS

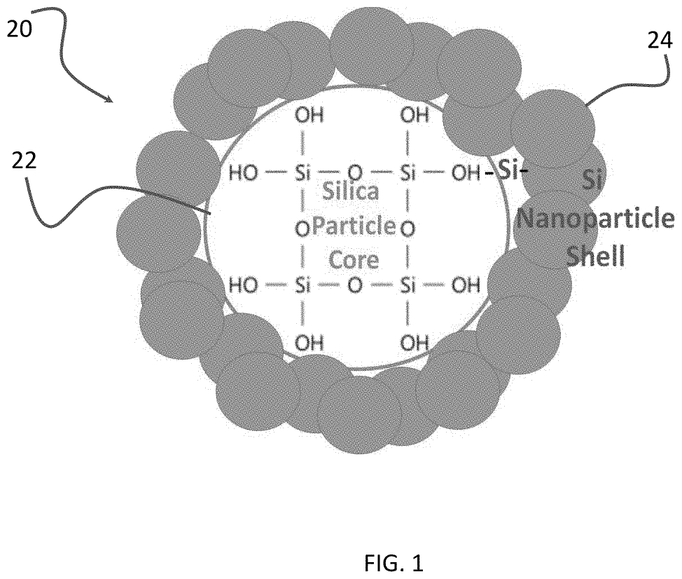

An embodiment of the invention is a core-shell nanophosphor 20, as shown in FIG. 1. In the core-shell nanophosphor 20, a (larger) silicon nanoparticle core 22 has a shell 24 of smaller silicon (Si) nanoparticles. In this example, the core 22 is provided by a silica particle, while the silicon nanoparticles constitute the shell 24. In the nanophosphor 20 of FIG. 1, the connection between the core 22 and the shell 24 is achieved through hydrogen bonding (H-bonding). In hydrogen bonding, hydrogen in the Si—H termination coating on the silicon nanoparticle connects to an oxygen in the silica, to form a strong H—O bond.

When irradiated, the luminescence resulting from the nanophosphor 20 is due to the sum of the luminescence from the shell 24 and from the core 22. The preferred nanophosphor 20 can emit white light.

A preferred method to form the FIG. 1 nanophosphor 20 is to mix a silicon nanoparticles (SiNp) colloid with room temperature vulcanizing material (RTV) and transfer them to a solid state. Drying SiNp in isopropyl alcohol in a plate in which there is glass powder can be used for the transfer. Because the silica particles are in the range of, e.g,. 50-200 nm in diameter, the much smaller Si nanoparticles (e.g., 3 nm in diameter) stick to the silica particles. Upon slow drying, the Si nanoparticles form a coating on the silica with insignificant number drying on the much smoother dish or bottle container.

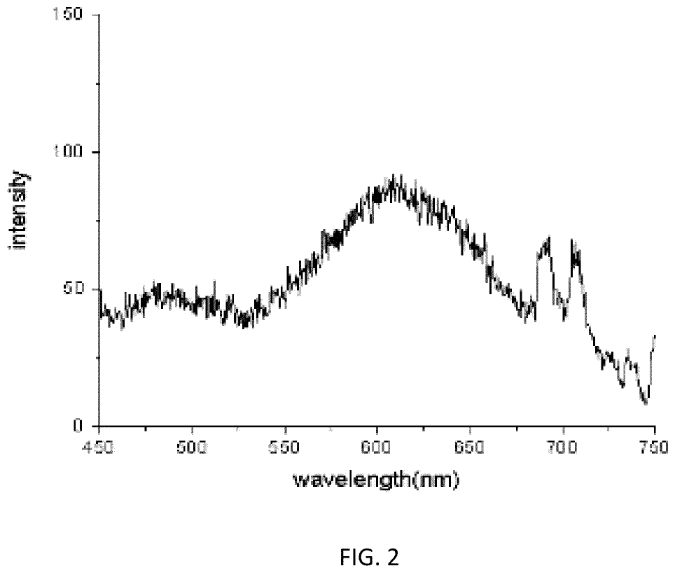

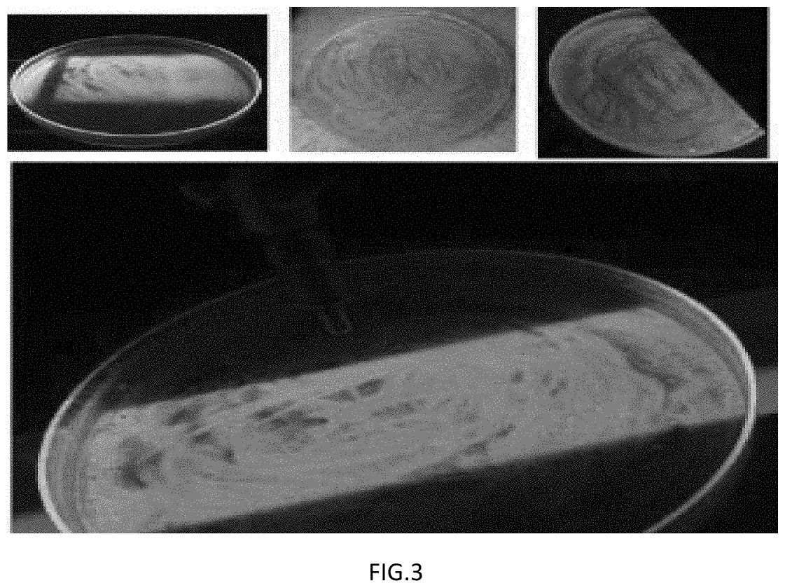

The luminescent spectrum of the coated glass powder is shown in FIG. 2. It shows the red luminescence band, characteristic of the silicon nanoparticles and a weaker blue-green band of the silica. The emission intensity increases with increasing amount of SiNp. However, it is somewhat limited due to the non-transparency of glass powder when it is thick. Examples of photos of luminescent core-shell (Si nanoparticle-silica) powder taken with 365 nm irradiation (shown in FIG. 3). In the photo from the top, the purple particle in the above graph is plastic, due to the scratching process to gather spreading glass powder) (under 254 nmUV).

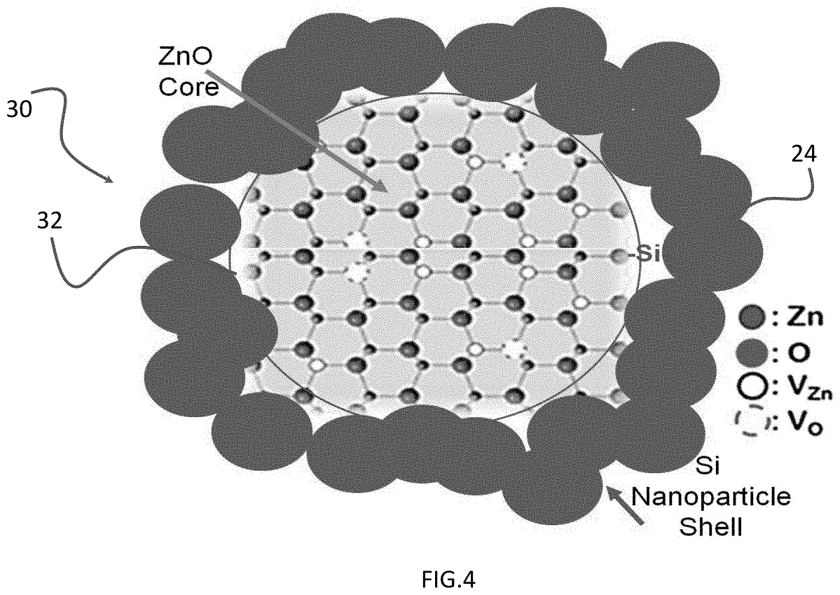

Other embodiments of the invention include different material cores with the shell of silicon nanoparticles. FIG. 4 shows a preferred Zn based core shell nanophosphor 30 having a Zn-based core 32. Zn-based powders, (which are much stronger luminescence material when they are doped) may be used. Powders of zinc oxide (ZnO) or zinc sulfide (ZnS) as shown in FIG. 4 are included, and can also be doped.

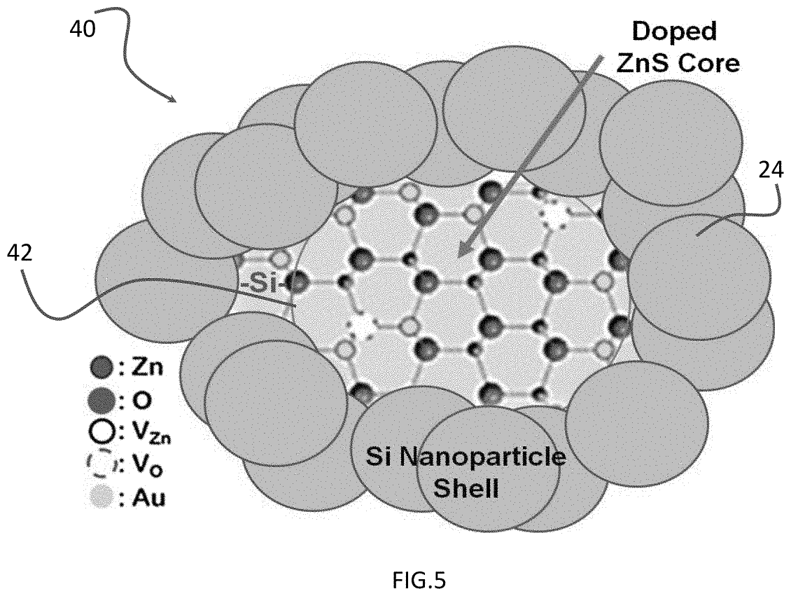

When the Zn-based powders are pre-doped with metal ions they become highly luminescent in the visible range of the spectrum depending on the type of metal used. When, for example, ZnS is doped with silver (Ag) ions (ZnS:Ag) it becomes blue luminescent. On the other hand, when ZnS is doped with copper, aluminum, and gold (ZnS:Cu,Au,Al) it becomes green luminescent. Thus creating a core-shell powder of the latter as shown in the nanophosphor 40 in FIG. 5 having a doped ZnS core 42, the resulting hybrid material becomes highly luminescent in the green and in the red simultaneously as it integrates the activity of the core with the activity of the shell. As another example, when the core-shell is formed with the former (ZnS:Ag) and the silicon nanoparticles 24, a hybrid that integrates blue luminescence with the red luminescence of the Si nanoparticles is provided.

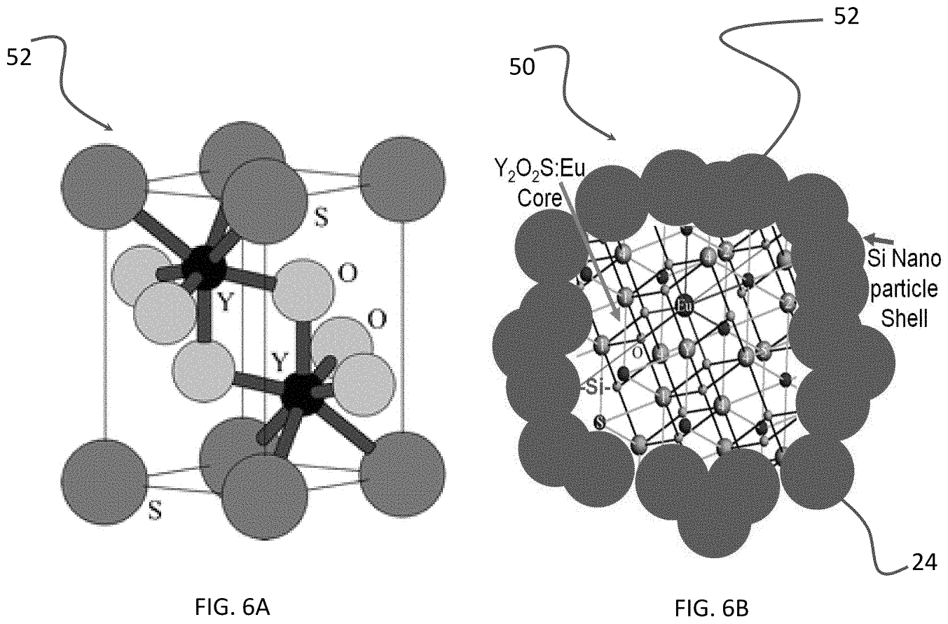

As another example, when a core-shell is formed with the red phosphor yttrium oxide-sulfide (FIG. 6A—shows the crystalline structure of the material) activated with europium (Y₂O₂S:Eu) (core 52) and the silicon nanoparticles 24, a hybrid core-shell 50 (FIG. 6B) that integrates red luminescence of the red phosphor with the red luminescence of the Si nanoparticles is provided.

The optical characteristics confirm an enhanced red phosphor including (or in some examples consisting of) a mixture of standard red phosphors and silicon nanoparticles. Standard red phosphors produce sharp emission lines while the nanoparticles produce wide band emission. The overall emission can enable, for instance, filling the missing component of present-day light emitting diode-based (LED-based) white bulbs.

Table 1 shows a summary of preferred embodiment enhanced core-shell nanophosphors, though this list is not exhaustive and other combinations are contemplated herein:

TABLE 1
SiNp

| | |
|---|---|
| Silica | Silica-SiNp core-shell |
| Blue phosphor | Blue phosphor-SiNp core-shell |
| Green phosphor | Green phosphor-SiNP core-shell |
| Red phosphor | Red phosphor-SiNp core-shell |

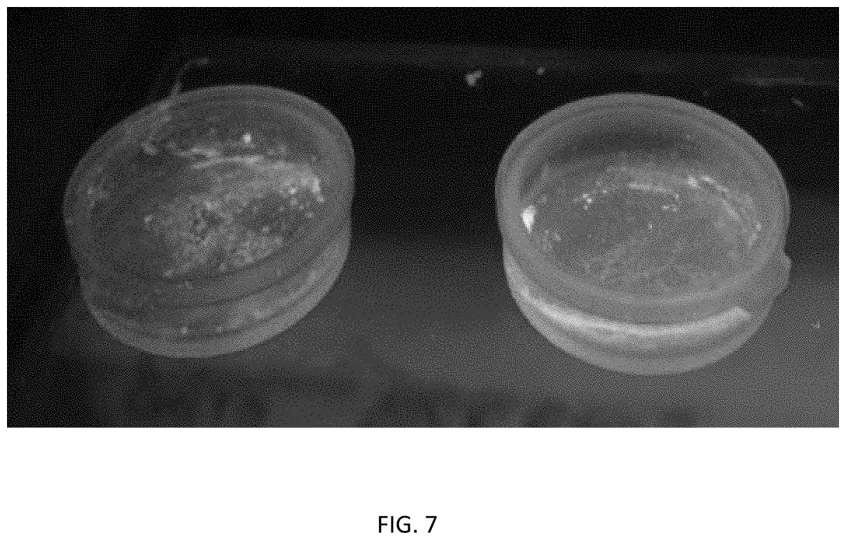

The effect of solvent on the formation of SiNp/silica core-shell with regard to example transfer processes was studied. The cases of SiNp in isopropyl alcohol with that in Tetrahydrofuran (THF) were compared. FIG. 7 shows luminescent photos for both cases under UV irradiation. The image on the left is that of SiNp in THF, while the image on the right is that of SiNp in isopropyl alcohol. Both cases work. THF is found however to be worse than alcohol with regard to RTV curing.

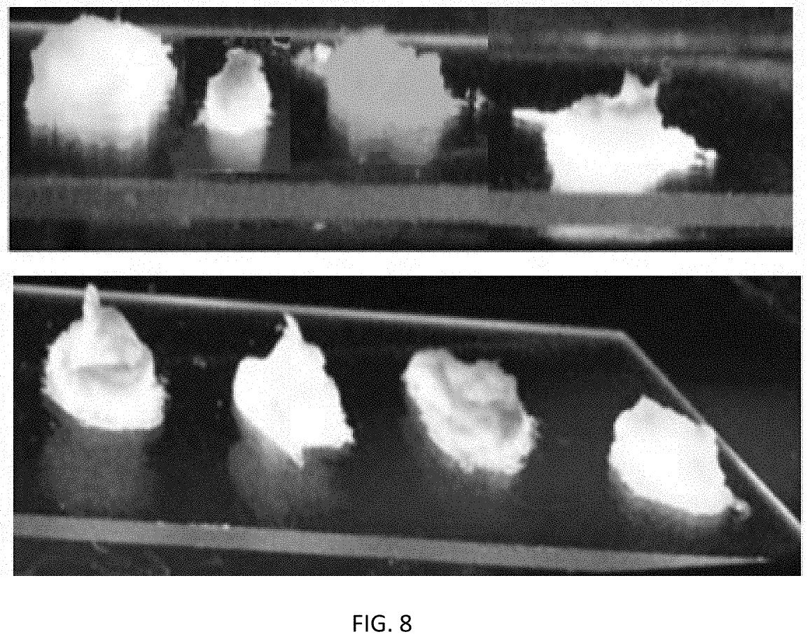

For illustration, the silica/SiNp core-shells were tested. Three ingredients: (i) SiNp/silica core-shell (ii) green ZnS based phosphor and (iii) blue ZnS based phosphor to get white light were mixed. FIG. 8 (top) gives from left to right green, red, blue and white. FIG. 8 (bottom) shows four different white mixtures with different shades of resulting white.

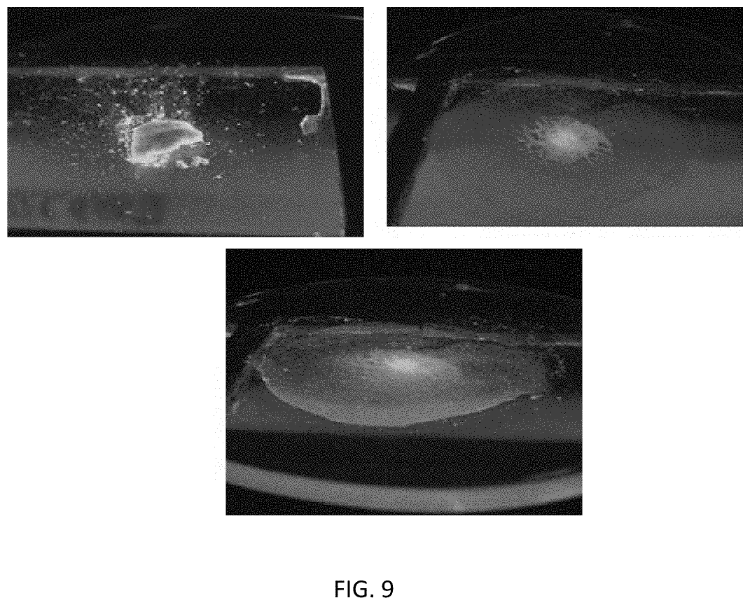

Environmental effects, such as the effect of PH and water, were tested. The effect of water on nano silicon is explained using FIG. 9. The original sample is on top under UV. Water was added such that the Si/silica core-shell is immersed in water. The particles are found to float on the surface. This is due to hydrophobicity of silicon.

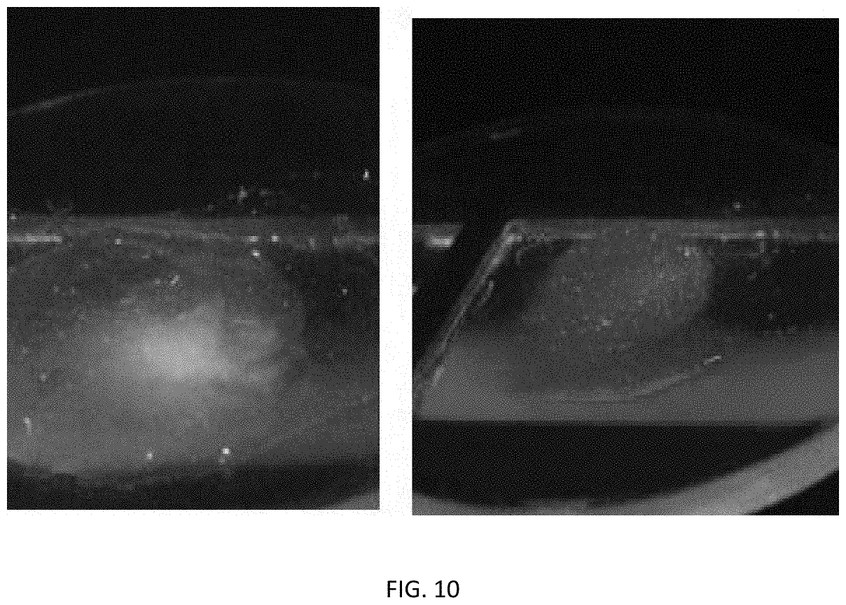

The viability of SiNp in acid (HCl) (FIG. 10 left) was also tested. It shows that the particles survive. On the other hand, the viability of SiNp in alkali (KOH) is not as good, as they tend to quench or dye (FIG. 10 right).

The connection between the silica, ZnO, ZnS, and Y₂O₂S and example nanoparticles provided herein to form the core-shell structures is unique. Because the silicon nanoparticles have hydrogen termination (H—Si termination), they are amenable to chemical routes that allows such connection through hydrogen bonding with oxygen/sulfur deficient sites or defects on the glass crystals. The above results (e.g., in FIGS. 3 and 8) show that using the SiNp/silica core shell component is advantageous. It allows independent control of the red nanophosphor component. Preferably, care is taken to avoid thickness of the phosphor powder that reduce transparency.

Preferred fabrication methods utilize wet chemistry to create the hybrid nanophosphor in the form of a core-shell. The chemicals used preferably should not compromise the optical properties of the semiconductor nanoparticles. Moreover, the semiconductor nanoparticles dispersion should be stable in the solution used. Preferred methods use isopropyl solvent for the nanoparticles and the dye. In a preferred method, a colloid of SiNp is mixed in isopropanol alcohol, with a colloid of phosphor powder in isopropanol alcohol. The phosphor forms an unstable colloid. Gentle shaking will allow mixing of the two components without compromising the sticking/connection of the two species core-shell architecture.

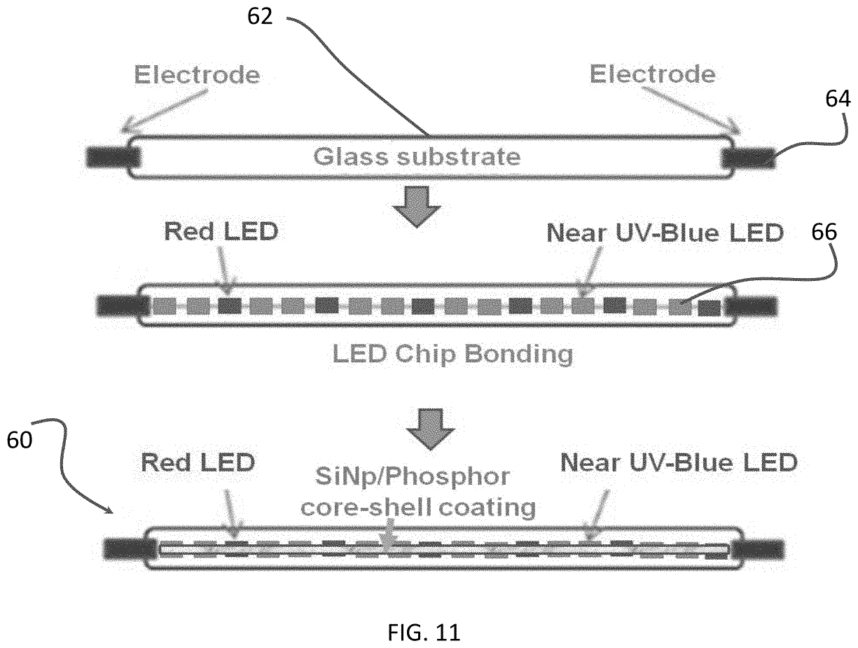

FIG. 11 shows an example fabrication method for a light emitting device 60 including example nanophosphors. A glass strip (substrate) 62 is fitted with electrodes 64 as shown in FIG. 11. An array of alternating near UV (NUV) or purple LEDs and red LED chips 66 is then bonded. This process is followed with placing a phosphor coating over the LEDs.

White LEDs can be generated using a coating including or consisting of a mixture of three phosphors: red, green and blue (RGB). Any three RGB combinations of phosphors given in Table 1 can be used. However, a preferred method is to use the high efficiency Y₂O₂S:Eu/SiNP core-shell (europium based red integrated with the red of the silicon nanoparticles) as the red component, and a ZnS-based blue emitting phosphor and a ZnS-based green emitting phosphor. In this configuration, the red component consists effectively of three emitters: a red LED, red phosphor and red emitting silicon nanoparticles. The red LED emission is a smooth but somewhat narrow band, while the red phosphor emission consists of many sharp lines, while the emission of the SiNp is a smooth wide band spectrum. In other words, the combination enables filling the missing red component of present-day LED based white bulbs.

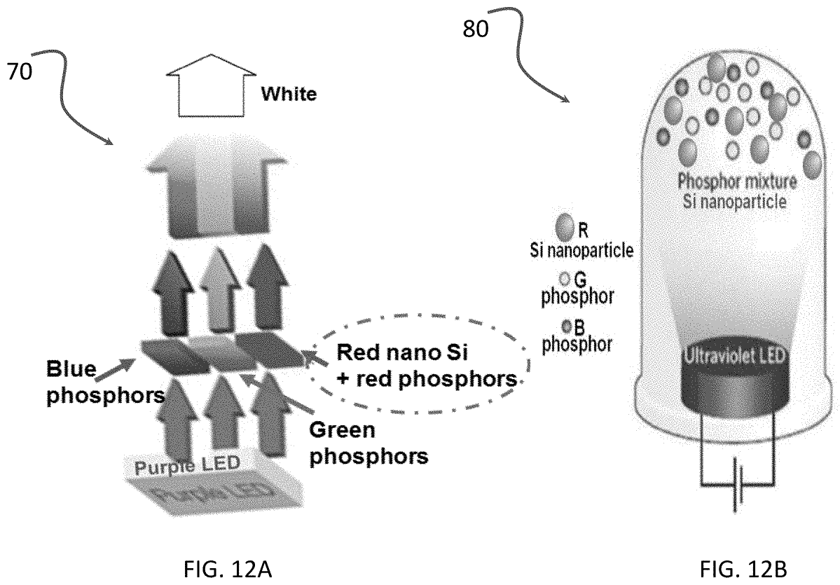

Other variations of the best model is to eliminate the red LED in the LED chip bonding process as shown in the light emitting device 70 (FIG. 12A), or to eliminate both the red LED and the red phosphor as shown schematically in the light emitting device 80 in FIG. 12B. When this enhanced core-shell nano-red phosphor is mixed with smooth blue and smooth green phosphor emission, it is possible to generate high quality white light. The mixing ratio can be designed such that the resulting light exhibits a high CRI percentage while independently achieving the specific temperature CCT temperature in the range 2600-6700, appropriate for a given application. Such applications include standard bulbs as well as filamentary bulbs.

While specific embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A nanophosphor, comprising a nanoparticle core having an attached shell of smaller silicon nanoparticles attached via hydrogen bonding.

2. The nanophosphor of claim 1, wherein the nanoparticle core comprises silica.

3. The nanophosphor of claim 2, wherein the nanoparticle core is doped with metal ions.

4. The nanophosphor of claim 1, wherein the nanoparticle core comprises ZnO.

5. The nanophosphor of claim 4, wherein the nanoparticle core is doped with metal ions.

6. The nanophosphor of claim 1, wherein the nanoparticle core comprises ZnS.

7. The nanophosphor of claim 6, wherein the nanoparticle core is doped with metal ions.

8. The nanophosphor of claim 1, wherein the nanoparticle core comprises yttrium oxide-sulfide activated with europium (Y₂O₂S:Eu).

9. The nanophosphor of claim 8, wherein the nanoparticle core is doped with metal ions.

10. The nanophosphor of claim 1, wherein the nanoparticle core comprises one or more of a blue phosphor, a green phosphor, or a red phosphor.

11. A light emitting device comprising:
the nanophosphor of claim 1; and
a solid state light source bonded to said nanophosphor.

12. The light emitting device of claim 11,
wherein the solid state light source comprises:
a glass substrate;
one or more light emitting diodes (LEDs) bonded to said substrate; and
one or more electrodes coupled to said substrate;
wherein the nanophosphor comprises a phosphor coating disposed over said one or more LEDs.

13. A method for forming a nanophosphor comprising:
providing a silicon nanoparticle (SiNp) colloid including Si nanoparticles;
transferring the colloid to a solid state comprising particles of one or more of silica and/or phosphors; and
allowing drying such that the Si nanoparticles form a coating on the particles with hydrogen bonds.

14. The method of claim 13, wherein the solid state comprises a core powder; and
wherein the particles comprise one or more of silica, ZnO, ZnS, or yttrium oxide-sulfide activated with europium (Y₂O₂S:Eu).

15. The method of claim 14,
wherein said core powder is applied to a plate;
wherein said drying comprises drying the colloid in a solvent onto the plate with the core powder such that the Si nanoparticle forms a coating on the core powder with hydrogen bonds.

16. The method of claim 15, wherein the solvent comprises isopropyl alcohol, Tetrahydrofuran (THF), or hydrochloric acid (HCl).

17. The method of claim 14, wherein the core powder comprises a glass powder.

18. The method of claim 14,
wherein said providing the silicon nanoparticle (SiNp) colloid comprises mixing a silicon nanoparticle (SiNp) colloid with room temperature vulcanizing material (RTV) to provide a mixture; and
wherein said transferring the colloid comprises transferring the mixture to the solid state.

19. The method of claim 14, wherein the method further comprises doping the core powder with metal ions.

20. A method for making a light emitting device, the method comprising:
providing a glass substrate;
coupling one or more electrodes to said substrate;
bonding one or more light emitting diodes (LEDs) to said substrate, the one or more LEDs including one or more of red, green, or blue phosphors;
providing a nanophosphor, the nanophosphor comprising a nanoparticle core having an attached shell of smaller silicon nanoparticles attached via hydrogen bonding; and
bonding said nanophosphor over said one or more LEDs to provide a phosphor coating.
